(19) United States
(12) Patent Application Publication
(10) Pub. No.: US 2026/0171182 A1
(43) Pub. Date: Jun. 18, 2026

(54) Reprogrammable Memory Repair

(71) Applicant: Google LLC, Mountain View, CA (US)

(72) Inventor: Mayank Parasrampuria, Bangalore (IN)

(73) Assignee: Google LLC, Mountain View, CA (US)

(21) Appl. No.: 18/985,856

(22) Filed: Dec. 18, 2024

(51) Int. Cl. G11C 29/44

(52) U.S. Cl. CPC G11C 29/4401

(57) ABSTRACT

Aspects of reprogrammable memory repair are disclosed. For example, blown-fuse data may be configured to prevent access to faulty locations within a memory. However, the blown-fuse data may include incorrect faulty locations or additional faulty locations may be determined after the fuse data was blown. A repair-word may be applied to invalidate a specified word stored at a faulty location. The repair-word modifies a memory subsystem portion of the word, a specified memory of the memory subsystem portion of the word, or the entire specified word itself to prevent access of the memory location and redirect access to a redundant location within the memory. Alternatively, the repair-word may be configured to erase, invalidate, or modify a specified word stored within fuse data. In another aspect, automatic test equipment may be configured to modify a single entry of the fuse data stored within a shadow storage.

### BACKGROUND

Electronic devices include semiconductor devices having memory, such as memory on a system-on-chip (SoC). The memory may include one or more faulty memory locations that may be detected during testing. As a precaution, the memory on the semiconductor device typically may include redundant columns and rows of memory that may be used in place of memory determined to be faulty. For example, a fuse (e.g., one-time programmable memory) may be blown to prevent access to a row or column of memory that includes a faulty memory location. The programming of the data contained within a fuse may be referred to as blown-fuse data or a blown fuse. The blown-fuse data redirects memory access to a redundant column or redundant row of memory instead of accessing a faulty memory location. Once the fuse data is blown, the access to memory locations may no longer be reprogrammed, which may be problematic. For example, a memory location may have been mistakenly identified as being faulty and/or a memory location may be determined as being faulty after the fuse has been blown.

### SUMMARY

This document describes systems and techniques directed at reprogrammable memory repair, which may overcome or reduce the disadvantages of not being able to correct fuse data (e.g., a one-time programmable memory) after it is blown. For example, a word that is stored in a faulty memory location that was not included in the blown fuse may be repaired by invalidating the word via a repair-word so that the faulty memory location may no longer be accessible. As used herein, reprogrammable memory repair means changing the access to a memory location (e.g., preventing access to a faulty memory location that was previously prevented by the blown fuse or allowing access to a memory location to which access was prevented by a blown fuse).

The system allows to invalidate the repair-word by modifying a portion of the word that indicates a memory subsystem, by modifying a portion of the word that indicates a specific memory within the memory subsystem, or by modifying the entire word. In another aspect, a new repair word can be blown into a fuse to override an existing repair-word which modifies built-in signature register data (e.g., signature) for a memory. In yet another aspect, automatic test equipment operating in soft-repair mode may be configured to invalidate, erase, or modify a specified word from fuse data, the specified word being stored in a shadow storage that includes at least a portion of the fuse data. The automatic test equipment may invalidate, erase, or modify the specified word in the shadow storage without the need to download the entire fuse data offline.

Aspects of reprogrammable memory repair are disclosed. For example, blown-fuse data may be configured to prevent access to faulty locations within the memory. However, the blown-fuse data may include incorrect faulty locations, or additional faulty memory locations may have been determined after the fuse data was blown. A repair-word may be applied to invalidate a specified word stored at a faulty location. The repair-word modifies a memory subsystem portion of the word, a specified memory of the memory subsystem portion of the word, or the entire specified word itself to prevent access of the memory location and redirect access to a redundant location within the memory. Alternatively, the repair-word may be configured to erase, invalidate, or modify a specified word stored within fuse data. In another aspect, automatic test equipment may be configured to modify a single entry of the fuse data stored within a shadow storage.

In some aspects, the techniques described herein relate to a method including determining a memory location in need of repair, the memory location containing a word and being located within fuse data. The memory location in need of repair may be a faulty memory location that blown-fuse data does not prevent access to. The memory location in need of repair may be a memory location that is not faulty but has been mistakenly identified as being a faulty memory location. A word stored at the memory location in need of repair may need to be invalidated, erased, or modified.

The method including determining a repair-word to be applied to the word stored at the memory location within the fuse data, the repair-word including a first portion indicating a memory subsystem of the memory location in need of repair, a second portion indicating a specific memory within the memory subsystem of the memory location, and a third portion indicating built-in signature register data (e.g., signature) for the memory location. The method including applying the repair-word, by a repair controller, to the word stored at the memory location within the fuse data, the applying effective to invalidate the word stored at the memory location within the fuse data by modifying the first portion, the second portion, or the first, second, and third portions of the repair-word.

In some aspects, the techniques described herein relate to a method including downloading, from a fuse, at least a portion of fuse data to a shadow storage. The method including determining a memory location in need of repair, the memory location being identified within fuse data downloaded to the shadow storage. The method including overwriting, with automatic test equipment, word data within the memory location in need of repair.

In some aspects, the techniques described herein relate to a system including a fuse having a plurality of memory locations, each memory location of the plurality of memory locations containing a word. The system includes a fuse controller coupled with the fuse, the fuse controller configured to access the plurality of memory locations. The system includes a repair controller coupled with the fuse controller, the repair controller configured to individually repair the word of a selected location of the plurality of memory locations.

This Summary is provided to introduce simplified concepts of reprogrammable memory repair, the concepts of which are further described below in the Detailed Description and Drawings. This Summary is not intended to identify essential features of the claimed subject matter, nor is it intended for use in determining the scope of the claimed subject matter.

### BRIEF DESCRIPTION OF THE DRAWINGS

The details of one or more aspects of systems and techniques directed at reprogrammable memory repair are described in this document with reference to the following drawings, in which the use of same numbers in different instances may indicate similar features or components.

FIG. 1 illustrates an example system that can implement aspects of reprogrammable memory repair.

FIG. 2 illustrates a schematic of an example repair-word that can implement aspects of reprogrammable memory repair.

FIG. 3 illustrates an example system that can implement aspects of reprogrammable memory repair.

FIG. 4 illustrates an example system that can implement aspects of reprogrammable memory repair.

FIG. 5 illustrates an example operating environment in which aspects of reprogrammable memory repair can be implemented.

FIG. 6 illustrates an integrated circuit component in which aspects of reprogrammable memory repair can be implemented.

FIG. 7 illustrates an example electronic device having internal hardware configured for reprogrammable memory repair in accordance with one or more implementations.

FIG. 8 is a flow chart of a method for repairable memory repair.

FIG. 9 is a flow chart of a method for repairable memory repair.

### DETAILED DESCRIPTION

### Overview

A semiconductor device typically includes one or more memories each having hundreds or thousands of memory locations (e.g., memory bits). A built-in self-test interface may test each memory location for faults with a built-in redundancy analysis within the built-in self-test interface configured to determine how to repair the memory (e.g., determine which row(s)/column(s) to prevent access to and which redundant row(s)/column(s) to use instead). The determination of the built-in redundancy analysis is applied to a built-in signature register coupled with the memory. The built-in signature register is used to blow fuse data to prevent access to faulty row(s) and/or column(s) identified as containing a faulty memory location and instead redirect access to allocated redundant row(s) and/or column(s) in place of the faulty row(s) and/or column(s) that include faulty memory locations.

The fuse is a one-time programmable (OTP) element that retains data, this data can be used to prevent access to (repair) rows and/or columns including faulty memory locations with no way to modify the fuse data once blown. Thus, errors, which may be the result of user error during testing, made in the identification of faulty row(s) and/or columns(s) may not be corrected after the fuse data is blown. In other words, there is no way to admit access to a row and/or column that has been previously identified as containing a faulty memory location with the blown-fuse data configured to prevent access to the identified faulty memory locations. Likewise, additional faults, which were not identified prior to the fuse being blown, also may not be repaired (e.g., preventing access). Further, if the testing of the memory was incomplete, there is no simple way to change, or modify, the fuse data after it has been blown. The blown-fuse data may potentially be corrected by downloading the entire fuse data offline, correcting the data, and uploading the corrected fuse data to the fuse. This is very time-consuming and not a feasible memory repair technique.

Presently, reprogrammable fuses (e.g., erasable programmable read-only memory) may be used to reprogram fuse data to correct faulty memory locations. However, such reprogrammable fuses are large in size, so they may not be applicable in a semiconductor device with spatial constraints. Additionally, current reprogrammable fuses are expensive in comparison to typical fuse controllers. Typical reprogrammable fuses are generally not available for use in latest-tech nodes but rather may be applicable for use in highly mature nodes. Thus, such reprogrammable fuses are not typically usable for cutting-edge technologies.

When testing memory, the memory needs to be tested across various operating conditions. For example, the built-in self-test interface may be used up to ten (10) times each with a different operating condition of the semiconductor device in an attempt to identify faulty locations within the memory. The data for each of the tests is consolidated offline to ensure that the blown-fuse data includes all of the faulty memory locations. The use of multiple tests consumes valuable time and does not ensure all faulty memory locations are identified. For example, a faulty memory location may appear during an operating condition of the semiconductor device that was not tested.

One technique to “correct” blown-fuse data is the use of a soft repair. Soft repair may be used to validate the faults prior to blowing the fuse data and enables a one-time patch for the memory to overcome mistakes within the fuse data. However, soft repair requires time to implement and is not a retained correction mechanism. Once an electronic device utilizing the memory is turned off, the patch is not available the next time the electronic device is turned on.

Another potential technique to correct blown-fuse data is downloading the entire content of a built-in signature register coupled with a memory, modifying the entire downloaded data, and then uploading the modified data to the built-in signature register. This is a very time-consuming, inefficient process. There is not a way to simply modify an entry within the built-in signature register without downloading the entirety of the data.

Mistakes in blown-fuse data, such as user errors, may result in costly and/or time-consuming repairs and may even render hundreds or thousands of memory parts useless. To this end, this document describes systems and techniques directed at reprogrammable memory repair. For example, the systems and techniques disclosed herein enable modifying a portion of a single word to prevent access to a faulty memory location.

In one implementation, the systems and techniques described herein may include invalidating a specific word at a specified location (e.g., a faulty memory location) within blown-fuse data. The specified word is invalidated by modifying the specified word with a repair-word. Each word includes at least a first portion, a second portion, and a third portion. Each portion of the word includes bits that are a combination of 0s and 1s. As described herein, the specified word may be invalidated by reprogramming the first portion, the second portion, or all three portions of the specified word. The first portion of the word indicates a memory subsystem, the second portion of the word indicates a specific memory within the memory subsystem, and the third portion of the word indicates a signature (e.g., the built-in register data) of the word. The memory is designed so that no word would include all 0s or all 1s in each portion of the word. Simply put, there is no memory subsystem location that corresponds to all 0s or all 1s. Likewise, there is not a memory within a memory subsystem that corresponds to all 0s or all 1s. The repair-word is applied to the specified word to modify the first portion of the specified word, the second portion of the specified word, or all three portions of the specified word. By modifying, by application of the repair-word, each bit of the respective portion of the specified word to be all 1s, the word is invalidated. The invalidation of a word prevents access to the faulty memory location (e.g., the memory location of the specified word).

In another implementation, the system and techniques described herein may include modifying a word stored in fuse data based on location-based priority. The fuse is a memory that stores words with each word associated with an address. The fuse stores a plurality of words each with a sequential address. The higher the address of a word, the higher the location-based priority. A repair controller may be configured to communicate a repair-word to the fuse. A repair-word is sent, from the repair controller, to the fuse. The repair-word includes a specified memory location (memory subsystem and specific memory within the memory subsystem). The first portion of the repair-word indicates a specific memory subsystem, and the second portion of the repair-word indicates a specific memory within the identified memory subsystem. The fuse will replace (e.g., overwrite) the word with the repair-word if a word stored within the fuse is associated with the specified memory location. In other words, the third portion (e.g., signature) of the word with the same specified memory location will be overwritten with the third portion (e.g., signature) of the repair-word.

A second repair-word, for the same specified memory location, may be sent to the fuse after the prior repair-word. The signature of the second repair-word will overwrite the signature of the current word (e.g., the prior repair-word) stored within the fuse. In this way, corrections to the fuse may be made with the repair controller. In this way, the third portion (e.g., signature) of any word stored in a fuse may be repaired (e.g., reprogrammed). The repair-word is sent to the location within the fuse data corresponding to the first portion and the second portion of the word. The third portion of the repair-word will overwrite the third portion of the word previously stored in the fuse data and the location corresponding to the first and second portions of the repair-word. This technique enables the correction of memory faults discovered after the fuse data has already been blown.

In yet another implementation, the system and techniques described herein may include downloading fuse data from a fuse to a shadow storage. In a soft-repair mode, automatic test equipment is configured to access and modify a single entry (e.g., a single word) stored in the shadow storage. The automatic test equipment is configured to invalidate, erase, or modify a specified word in the shadow storage. The corrected (e.g., invalidated, erased, or modified) word may then be applied to the fuse data without the need to download the entire fuse data offline to make such a correction.

The following discussion describes operating environments, techniques that may be employed in the operating environments, and example methods. Although techniques using and apparatuses for reprogrammable memory repair are described, it is to be understood that the subject of the appended claims is not necessarily limited to the specific features or methods described. Rather, the specific features and methods are disclosed as example implementations and reference is made to the operating environment by way of example only.

### Example Systems and Operational Schemes

Reprogrammable memory repair enables blown-fuse data to be modified if a faulty memory location is determined after the fuse data has been blown. The reprogrammable memory repair enables the modification of the blown-fuse data to prevent access to a faulty memory location not included within the blown-fuse data. Similarly, reprogrammable memory repair enables blown-fuse data to be corrected if a faulty memory location was incorrectly identified and included within the blown-fuse data. The blown-fuse data may be modified to allow access to a memory location that is not faulty but was included as being faulty within the blown-fuse data, which would prevent access to such a location. The reprogrammable memory repair may enable the modification of one or more portions of a word to prevent access to a faulty memory location. In other aspects, the reprogrammable memory repair may enable modifications to words stored in the fuse data based on location-based priority. In yet another aspect, the reprogrammable memory repair enables blown-fuse data to be stored in a shadow storage and enables a single word to be erased, modified, or invalidated to change whether a memory location corresponding to the word may be accessed.

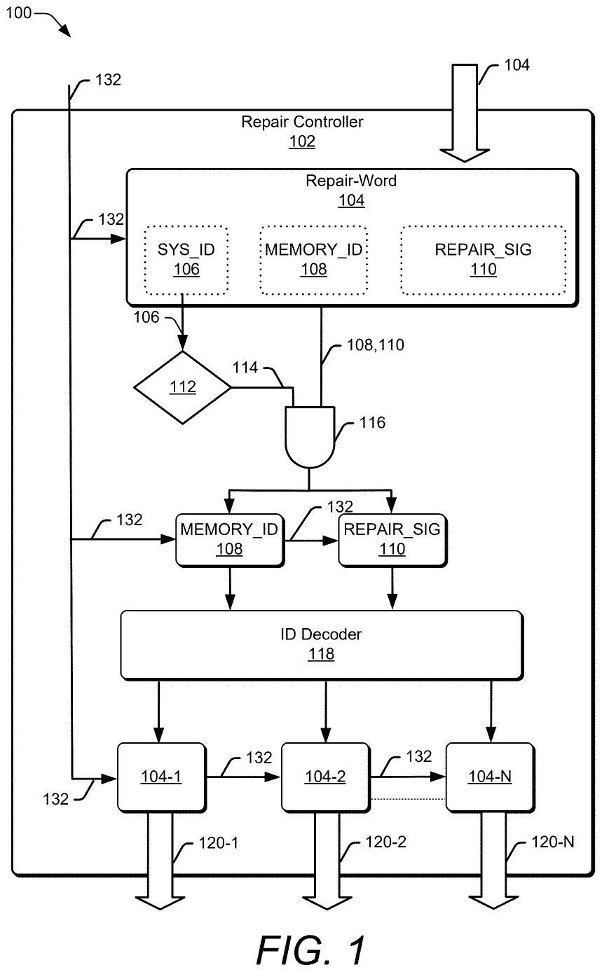

FIG. 1 illustrates an example system 100 that can implement aspects of reprogrammable memory repair. The system 100 includes a repair controller 102 that is configured to repair a word stored at a faulty memory location as discussed herein. The repair controller 102 receives a repair-word 104. The repair-word 104 includes a first portion (SYSTEM_ID 106), a second portion (MEMORY_ID 108), and a third portion (REPAIR_SIG 110). SYSTEM_ID 106 indicates a memory subsystem, MEMORY_ID 108 indicates a specific memory within the memory subsystem identified by SYSTEM_ID 106, and REPAIR_SIG indicates built-in signature register data (e.g., signature) of the repair-word.

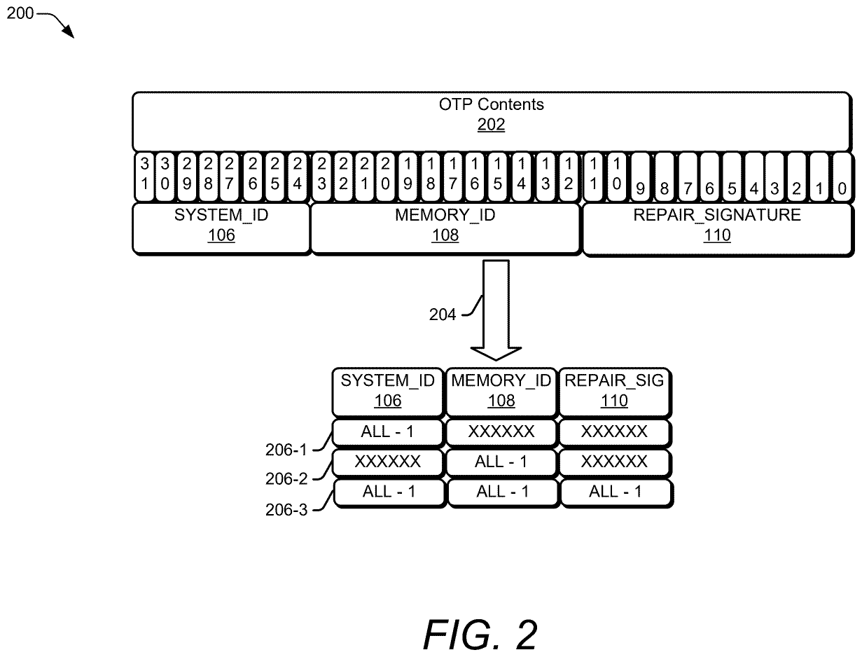

The SYSTEM_ID 106 (e.g., SYS_ID 106) is communicated to logic 112. The logic 112 determines whether the SYSTEM_ID 106 is valid. If valid, the logic 112 communicates 114 the SYSTEM_ID 106 to an AND gate 116. The MEMORY_ID 108 and the REPAIR_SIG 110 are communicated to the AND gate 116. In the event the AND gate 116 receives the MEMORY_ID 108, the REPAIR_SIG 110, and the SYSTEM_ID 106 communicated 114 from the logic 112, the MEMORY_ID 108 and the REPAIR_SIG 110 are communicated to an identification (ID) Decoder 118. The ID decoder 118 may communicate a first repair-word 104-1 to corresponding first memory location 120-1, a second repair-word 104-2 to a corresponding second memory location 102-2, or a third repair-word 104-N to a corresponding third memory location 120-N. The corresponding memory location (e.g., first corresponding memory location 120-1, second corresponding memory location 120-2, third corresponding memory location 120-N) is determined based on the SYSTEM_ID 106 the MEMORY_ID as would be appreciated by one of ordinary skill in the art having the benefit of this disclosure. A clock signal 132 external to the repair controller 102 may be communicated to the repair-word 104, the MEMORY_ID 108 and REPAIR_SIG 110 communicated to the ID decoder 118, and to the repair-words 104-1, 104-2, . . . 104-N communicated from the ID decoder 118 to the specified memory locations indicated by arrows 120-1, 120-2, . . . 120-N. The repair-word 104 may be used to invalidate a faulty memory location as discussed with regard to FIG. 2.

FIG. 2 illustrates a schematic 200 of a repair-word 204 that implements aspects of reprogrammable memory repair. Words are stored in the contents of a one-time programmable memory (OTP Contents 202). The OTP may be a fuse controller coupled with a fuse. A repair-word 204 may be used to invalidate a word stored at a faulty memory location. As discussed above, the repair-word 104 includes a first portion (SYSTEM_ID 106) that indicates a memory subsystem, a second portion (MEMORY_ID 108) that indicates a specific memory within the memory subsystem identified by SYSTEM_ID 106, and a third portion (REPAIR_SIGNATURE 110) that indicates built-in signature register data (e.g., signature) of the repair-word. The SYSTEM_ID 106 may be comprised of 8 bits, the MEMORY_ID 108 may be comprised of 12 bits, and the REPAIR_SIGNATURE 110 (also referred to as REPAIR_SIG 110) may also be comprised of 12 bits.

The repair-word 204 may prevent access to a faulty memory location. In one aspect as shown in row 206-1, the repair-word 204 invalidates a word by modifying the SYSTEM_ID 106 (e.g., the first portion) of the word. The word may be invalidated by changing all of the bits of the SYSTEM_ID 106 to contain the digit 1 without modifying the bits of the MEMORY_ID 108 or the REPAIR_SIG 110. There is not a memory subsystem that corresponds to “11111111”. Thus, the fuse controller will ignore the word because it does not map to any memory subsystem. In this way, this modification invalidates the word stored at the faulty memory location to prevent the faulty memory location from being accessed.

In another aspect as shown in row 206-2, the repair-word 204 invalidates the word by modifying the MEMORY_ID 108 (e.g., the second portion) of the word. The word may be invalidated by changing all of the bits of the MEMORY_ID 108 to contain the digit 1 without modifying the bits of the SYSTEM_ID 106 or the REPAIR_SIG 110. There is not a specific memory within the memory subsystem identified by the SYSTEM_ID 106 that corresponds to “111111111111”. Thus, the fuse controller will ignore the word because it does not map to any memory in a memory subsystem. In this way, this modification invalidates the word stored at the faulty memory location to prevent the faulty memory location from being accessed.

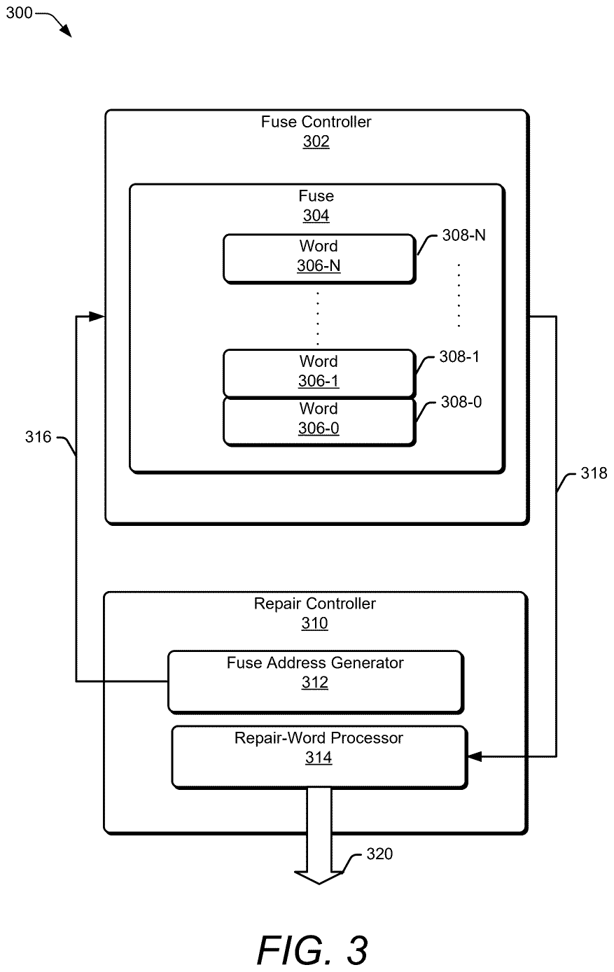

In yet another aspect shown in row 206-3, the repair-word 204 invalidates the word by modifying the SYSTEM_ID 106 (e.g., the first portion), the MEMORY_ID 108 (e.g., the second portion), and the REPAIR_SIG 110 (e.g., the third portion) of the word. The word may be invalidated by changing all of the bits of SYSTEM_ID 106, the MEMORY_ID 108, and the REPAIR_SIG 110 to contain the digit 1. This modification invalidates the word stored at the faulty location to prevent this faulty location from being accessed. Using the repair-word 204 enables the reprogramming of the OTP contents 202 to repair faulty memory locations to prevent access of faulty memory locations not originally contained in the blown-fuse data. The repair-word 204 may be used in aspects of reprogrammable memory repair by preventing access to faulty memory locations that was accessible in previously blown-fuse data. Yet another aspect of reprogrammable memory repair is providing location-based priority word correction as illustrated with regard to FIG. 3.

FIG. 3 illustrates an example system 300 that can implement aspects of reprogrammable memory repair. The system 300 includes a fuse controller 302 that includes fuse data (e.g., words) within a fuse 304. The fuse 304 includes a plurality of words 306-0, 306-1, . . . 306-N stored at a plurality of addresses 308-0, 308-1, . . . 308-N within the fuse 304. Each word (e.g., 306-0, 306-1, . . . 306-N) is associated with a single address (e.g., 308-0, 308-1, . . . 308-N) within the fuse 304. The fuse controller 302 is coupled with a repair controller 310 that includes a fuse address generator 312 and a repair-word processor 314. The words 306-0, 306-1, . . . 306-N of the fuse 304 are accessed (indicated by arrow 316) one at a time via the fuse address generator 312 within the repair controller 310. As each word is accessed, the word (e.g., 306-0, 306-1, . . . 306-N) is communicated (indicated by arrow 318) to the repair controller 310.

The words 306-0, 306-1, . . . 306-N are accessed (indicated by arrow 316) one at a time starting at the lowest address (e.g., address 308-0) of the fuse 304. If the address (e.g., 308-0, 308-1, . . . 308-N) is a valid address of the fuse 304, a signature of the word stored at the address is communicated (indicated by arrow 318) to the repair-word processor 314. After accessing the word (e.g., 306-0) at the lowest address (e.g., 308-0), the repair controller 310 progressively accesses the word (e.g., 306-1) at the next address (e.g., 308-1) until the last word (e.g., 306-N) at the last address (e.g., 306-8) has been accessed. The signature (e.g., REPAIR_SIG 110) of each word is communicated (indicated by arrow 318) to the repair-word processor 314 as well as the SYSTEM_ID 106 and the MEMORY_ID 108 (as described with respect to FIG. 1). If the word corresponds to a valid memory address (e.g., SYSTEM_ID 106 and MEMORY_ID 108), the signature (e.g., REPAIR_SIG 110) of the word (e.g., 306-0, 306-1, . . . 306-10) overwrites the REPAIR_SIG 110 (e.g., signature) of the word with a signature of a repair word. The “repaired” word is then communicated (indicated by arrow 320) to the specified memory location (e.g., SYSTEM_ID 106 and MEMORY_ID 108).

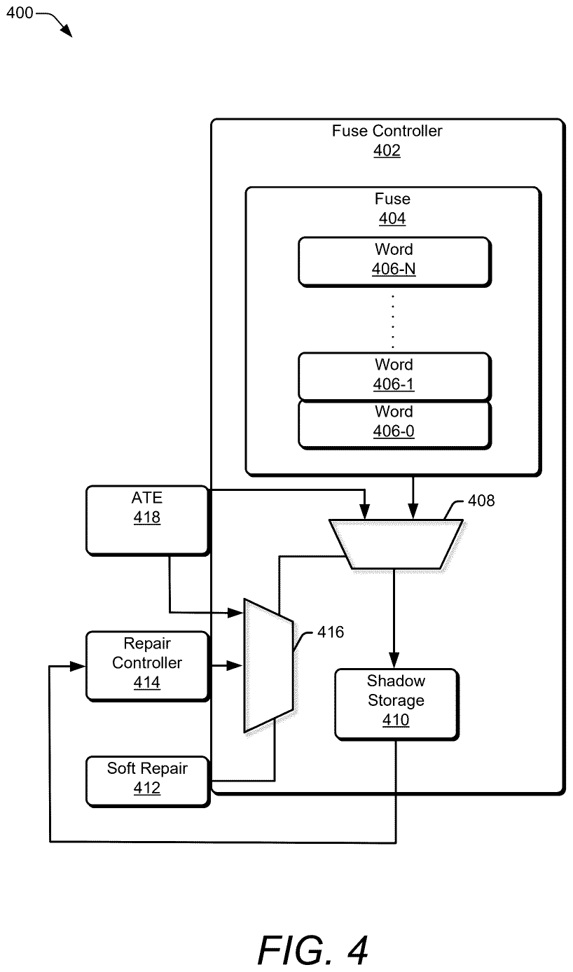

Each time the repair controller 310 receives a repair-word for a word stored at a valid specific memory location (e.g., a valid memory location specified by the SYSTEM_ID 106 and the MEMORY_ID 108 as discussed with regard to FIG. 1 and FIG. 2), the repair controller 310 overwrites the signature of the word stored at the specified location. In other words, the system 300 is configured to replace the word (e.g., the signature portion of the word) based on a higher location-based priority. Stated another way, the word (e.g., the signature portion of the word) will be replaced if a later repair-word is received for a corresponding word (e.g., word 306-0, 306-1, . . . 306-N) by the repair controller 310. This is because the repair controller 310 is configured to start accessing the lowest address (e.g., address 308-0) of the fuse 304 and progressively access each higher address until the highest address (e.g., address 308-N) of the fuse 304 is accessed. In this way, the repair controller 310 can be used to repair faulty memory locations. Further, the repair is reprogrammable as the fuse 304 may be programmed with data to repair faulty memory locations. Yet another aspect of reprogrammable memory repair is providing word modification and correction as illustrated with regard to FIG. 4.

FIG. 4 illustrates an example system 400 that can implement aspects of reprogrammable memory repair. The system 400 includes a fuse controller 402 that includes fuse data (e.g., fuse 404) that includes a plurality of words 406-0, 406-1, . . . 406-N stored within the fuse 404. The fuse controller 402 includes a first multiplexer 408 that couples a shadow storage 410 to the fuse 404. The shadow storage 410 is coupled with a repair controller 414. The repair controller 414 is coupled with a second multiplexer 416 that is also coupled with the first multiplexer 408. A soft repair 412 is coupled with the second multiplexer 416 and the first multiplexer 408 via the second multiplexer 416. The system 400 includes automatic test equipment (ATE) 418 coupled with the first multiplexer 408 and the second multiplexer 416. The system 400 is configured to enable a word to be invalidated, erased, or modified as discussed herein.

The fuse data (e.g., the words 406-0, 406-1, . . . 406-N stored within the fuse 404) is copied to the shadow storage 410 of the fuse controller 402. The first multiplexer 408 enables the fuse data to be copied to the shadow storage 410. The repair controller 414 sends a command to read specified fuse data (e.g., a word 406-0, 406-1, . . . 406-N) from the shadow storage 410. The shadow storage 410 sends the specified fuse data (e.g., a word 406-0, 406-1, . . . 406-N) to the repair controller 414 for processing. The soft repair 412 enables the ATE 418 to repair the specified fuse data (e.g., a word 406-0, 406-1, . . . 406-N). The ATE 418 can repair the specified fuse data (e.g., a word 406-0, 406-1, . . . 406-N) in a number of different ways.

For example, the ATE 418 can erase the specified fuse data (e.g., a word 406-0, 406-1, . . . 406-N) from the shadow storage 410. As another example, the ATE 418 can invalidate the specified fuse data (e.g., a word 406-0, 406-1, . . . 406-N) stored in the shadow storage 410. The word may be invalidated by changing a portion (e.g., the bits of the SYSTEM_ID 106, the bits of the MEMORY_ID 108) of the word to all 1s as discussed above. The word may also be invalidated by changing all of the bits (e.g., the bits corresponding to the SYSTEM_ID 106, MEMORY_ID 108, REPAIR_SIG 110) of the word to all 1s.

In some aspects, the ATE 418 can modify the specified fuse data (e.g., a word 406-0, 406-1, . . . 406-N) stored in the shadow storage 410. For example, the ATE 418 can modify the entire word or a portion of the word stored in the shadow storage 410. The ATE 418 may be configured to modify the signature portion (e.g., REPAIR_SIG 110) of a word stored in the shadow storage 410. The first multiplexer 408 and second multiplexer 416 enable communications of the various components of the system 400 as would be appreciated by one of ordinary skill in the art having the benefit of this disclosure. The system 400 of FIG. 4 provides reprogrammable memory repair of fuse data (e.g., fuse 404) without needing to download the entire contents of the fuse 404 offline. Further, the system 400 is configured to enable repair of a single entry (e.g., 406-0, 406-1, or 406-N) without repairing the entire contents of the fuse 404.

### Example Environments and Electronic Devices

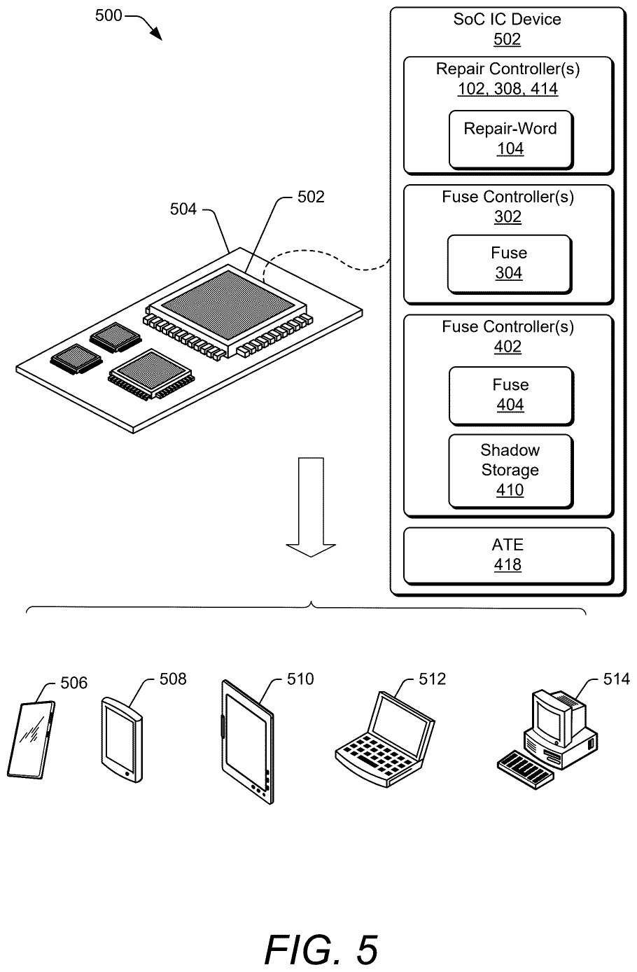

FIG. 5 illustrates an example operating environment 500 in which aspects of reprogrammable memory repair can be implemented. As illustrated, an SoC integrated circuit (IC) device 502 may be mounted to a printed circuit board (PCB) 504, which may be included as part of a computing device that implements one or more security protocols. As non-limiting examples, the computing device may be a smartphone 506, a personal digital assistant 508, a tablet 510, a laptop 512, or a workstation 514.

The SoC IC device 502 may include various memory elements that may include one or more faulty memory locations. The SoC IC device 502 may include one or more repair controller(s) 102, 308, 414, at least one repair-word 104, one or more fuse controller(s) 302, 402, one or more fuse(s) 304, 404, one or more shadow storages 410, and at least one automatic test equipment (ATE) 410 configured to repair one or more faulty memory locations. For example, the repair-word (e.g., repair-word 104) may prevent access to a faulty memory location by modifying a portion of a word stored at the faulty memory location or by modifying the entire word stored at the faulty memory location. As yet another example, the one or more fuse controllers 302 may modify a word stored in fuse data (e.g., words 306-0, 306-1, . . . 306-N) by applying a priority-based word correction. In one aspect, the one or more fuse controllers 402 may copy fuse data (e.g., words 406-0, 406-1, . . . 406-N) to a shadow storage 410 and use ATE 418 to invalidate, erase, or modify a word stored in the shadow storage 410.

Although the SoC IC device 502 is described in the context of a single SoC IC device including one or more repair controller(s) 102, 308, 414, at least one repair-word 104, one or more fuse controller(s) 302, 402, one or more fuse(s) 304, 404, one or more shadow storages 410, and one or more ATE units 418, a combination of discrete IC devices may perform the same functions. For example, a discrete processor IC device (e.g., one or more repair controller(s) 102, 308, 414, at least one repair-word 104, one or more fuse controller(s) 302, 402, one or more fuse(s) 304, 404, one or more shadow storages 410, and one or more ATE units 418) may work in combination with a discrete non-volatile memory IC device having the elements to perform one or more functions described herein.

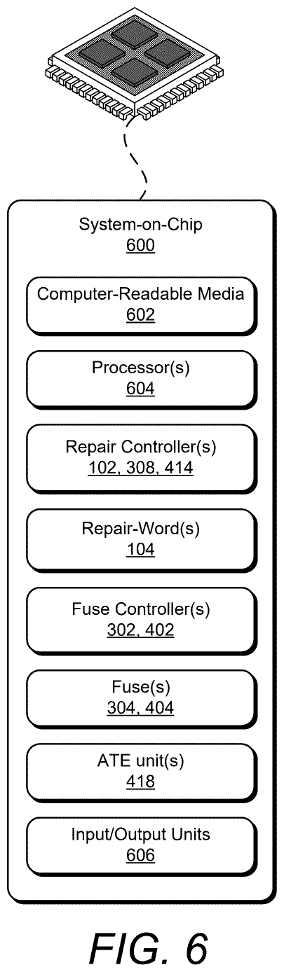

FIG. 6 illustrates an integrated circuit component implemented as an SoC 600 that can implement various aspects of reprogrammable memory repair. The SoC 600 may be a single chip including components that are fabricated on the same semiconductor substrate. Alternatively, the SoC 600 may be a number of such chips that are epoxied together. The SoC 600 can be implemented in any suitable device, such as a smartphone, a cellular phone, a netbook, a tablet computer, a server, a wireless router, a network-attached storage, a camera, a smart appliance, a printer, a set-top box, or any other suitable type of device. Although described with reference to an SoC, the entities of FIG. 6 may also be implemented as an application-specific integrated circuit (ASIC), a field-programmable gate array (FPGA), or the like.

The SoC 600 can be integrated with electronic circuitry, including the components described in the operating system listed herein. The SoC 600 can also include an integrated data bus (not shown) that couples the various components of the SoC 600 for data communication between the components. The integrated data bus or other components of the SoC 600 may be exposed or accessed through an external port, such as a joint test action group (JTAG) port. For example, components of the SoC 600 may be tested, configured, or programmed (e.g., flashed) through the external port at different stages of manufacture.

In this example, the SoC 600 includes computer-readable media 602, one or more processors 604, one or more repair controllers 102, 308, 414, one or more repair-words 104, one or more fuse controllers 302, 402, one or more fuses 304, 404, one or more ATE units 418, and input/output (I/O) units 606. The repair controller(s) 102, 308, 414 can be configured to repair faulty memory locations as described herein. The fuse controllers 302, 304 can be configured to enable modification of fuse data 304, 404 as described herein. The one or more ATE units 418 may be configured to enable modification of fuse data 304, 404 stored in a shadow storage as described herein. The computer-readable media 602 may be stored in computer-readable storage media, including one or more non-transitory storage devices such as a random-access memory (RAM), dynamic random access memory (DRAM), non-volatile random access memory (NVRAM), or static random access memory (SRAM), read-only memory (ROM), or flash memory, a hard drive, a solid-state drive (SSD), or any type of media suitable for storing electronic instructions, each coupled with a computer system bus.

The computer-readable media 602 of the SoC 600 may include executable code for reprogrammable memory repair. One or more of the processor(s) 604 operably coupled to computer-readable storage media having the computer-readable media 602 may execute instructions for reprogrammable memory repair.

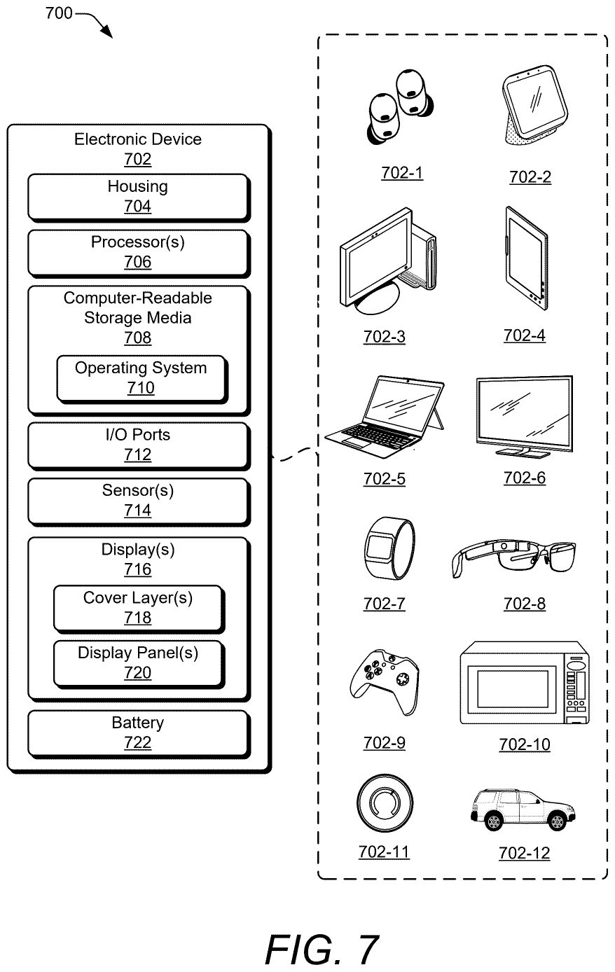

FIG. 7 illustrates an example environment 700 of an example electronic device 702 that includes reprogrammable memory repair in accordance with one or more implementations. The electronic device 702 may include additional components and interfaces omitted from FIG. 7 for the sake of clarity. The electronic device 702 is illustrated with various non-limiting example electronic devices 702, including wireless earbuds 702-1, a smart display associated with a home-automation and control system 702-2, a desktop computer 702-3, a tablet 702-4, a laptop 702-5, a television 702-6, a computing watch 702-7, computing glasses 702-8, a gaming system 702-9, a microwave 702-10, a smart thermostat interface 702-11, and an automobile having computing capabilities 702-12. Other devices may also be used, such as wired earbuds, a security camera, a trackpad, a drawing pad, a netbook, an e-reader, other forms of home-automation and control systems, a wall display, a virtual-reality headset, another vehicle (e.g., an e-bike or plane), and other home appliances, to name just a few examples. Note that the electronic device 702 may be wearable, non-wearable but mobile, or relatively immobile (e.g., desktops and appliances), all without departing from the scope of the present teachings.

The electronic device 702 includes a housing 704, which defines at least one internal cavity within which one or more of a plurality of electronic components may be disposed. In implementations, a mechanical frame may define one or more portions of the housing 704. As an example, a mechanical frame can include plastic or metallic walls that define portions of the housing 704. In additional implementations, a mechanical frame may support one or more portions of the housing 704. As an example, one or more exterior housing components (e.g., plastic panels) can be attached to the mechanical frame (e.g., a chassis). In so doing, the mechanical frame physically supports the one or more exterior housing components, which define portions of the housing 704. In implementations, the mechanical frame and/or the exterior housing components may be composed of crystalline or non-crystalline solids. In implementations, the housing 704 may be sealed through the inclusion of one or more displays (e.g., at least one display 716), defining at least one internal cavity.

The electronic device 702 may further include one or more processors 706. The processor(s) 706 can include, as non-limiting examples, an SoC, an application processor, a central processing unit, or a graphics processing unit (GPU). The processor(s) 706 generally execute commands and processes utilized by the electronic device 702 and an operating system installed thereon. For example, the processor(s) 706 may perform operations to display graphics of the electronic device 702 on the one or more displays 716 and can perform other specific computational tasks.

The electronic device 702 may also include computer-readable storage media (CRM) 708. The CRM 708 may be a suitable storage device configured to store device data of the electronic device 702, user data, and multimedia data. The CRM 708 may store an operating system 710 that generally manages hardware and software resources (e.g., the applications) of the electronic device 702 and provides common services for applications stored on the CRM 708. The operating system 710 and the applications are generally executable by the processor(s) 706 to enable communication and user interaction with the electronic device 702. One or more processors 706, such as a GPU, perform operations to display graphics of the electronic device 702 on the one or more displays 716 and can perform other specific computational tasks. The processors 706 can be single-core or multiple-core processors.

The electronic device 702 may also include input/output (I/O) ports 712. The I/O ports 712 allow the electronic device 702 to interact with other devices or users. The I/O ports 712 may include any combination of internal or external ports, such as universal serial bus (USB) ports, audio ports, serial advanced technology attachment (SATA) ports, peripheral component interconnect standard (PCI)-express based ports or card-slots, secure digital input/output (SDIO) slots, and/or other legacy ports.

The electronic device 702 may further include one or more sensors 714. The sensor(s) 714 can include any of a variety of sensors, such as an audio sensor (e.g., a microphone), a touch-input sensor (e.g., a touchscreen), an image-capture device (e.g., a camera, video-camera), proximity sensors (e.g., capacitive sensors), an under-display fingerprint sensor, or an ambient light sensor (e.g., photodetector). In implementations, the electronic device 702 includes one or more of a front-facing sensor(s) and a rear-facing sensor(s). The electronic device 702 may include various components. For example, the electronic device 702 may include processor(s) 706, computer-readable storage media 708, I/O ports 712, sensors 714, display(s) 716, a battery 722, or the like. The operating system 710 and/or various processor(s) 706 of the electronic device 702 may include operating instructions to enable reprogrammable repair of faulty memory locations.

The electronic device 702 may include the one or more displays 716, one or more cover layers 718, and one or more display panels 720. The cover layer(s) 718 may be implemented as any of a variety of transparent materials including polymers (e.g., plastic, acrylic) or glasses.

The electronic device 702 further includes a battery 722. In implementations, the battery 722 is a rechargeable battery that is configured to store and supply electrical energy. The rechargeable battery 722 may be any suitable rechargeable battery, such as a lithium-ion (Li-ion) battery.

### Example Methods

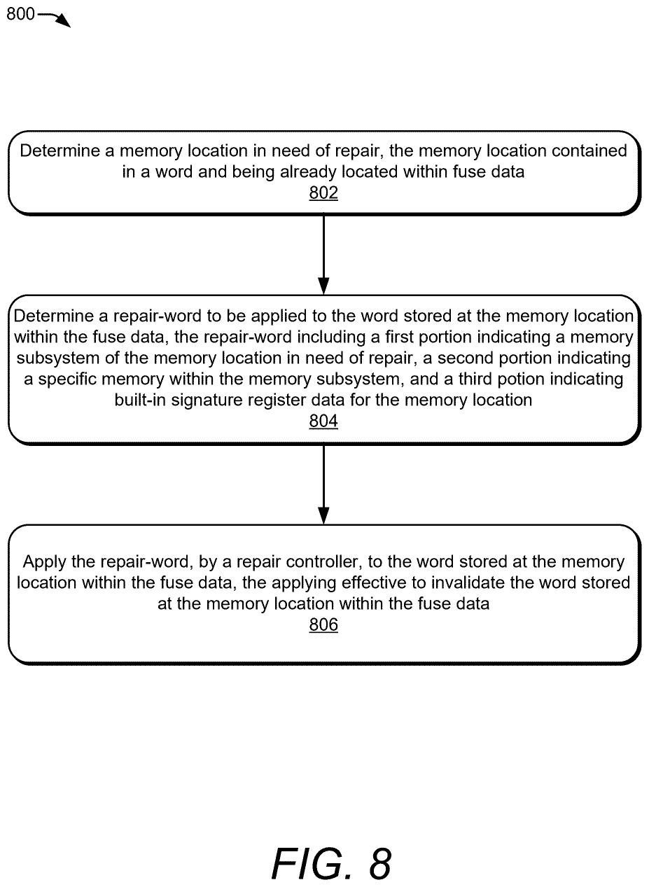

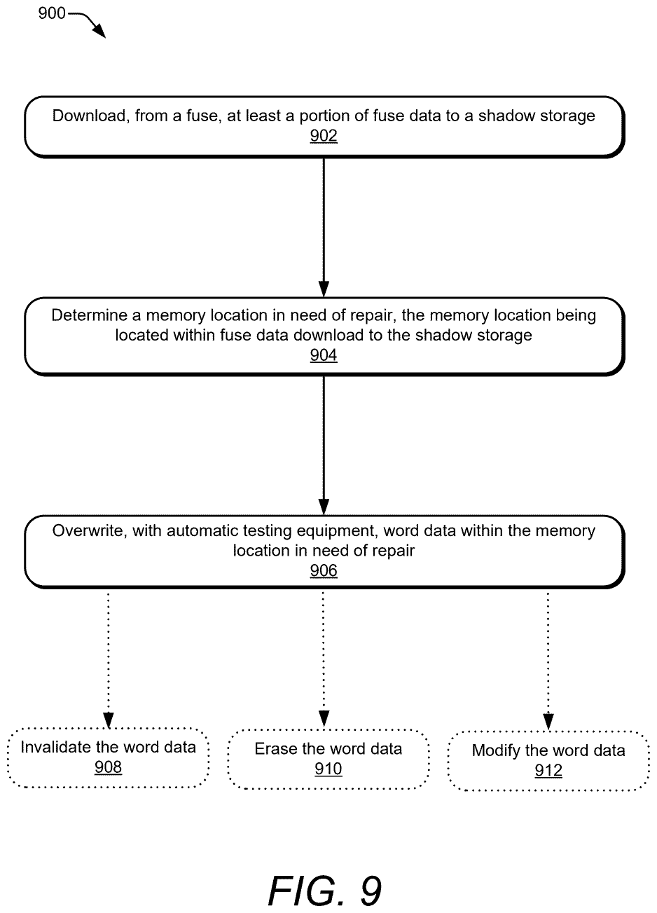

Example methods are described below with reference to the flowcharts of FIG. 8 and FIG. 9. Although example method aspects are described separately below, they may be implemented together in any combination or permutation.

FIG. 8 is a flowchart that illustrates a method 800 for reprogrammable memory repair, which includes operations 802 through 806. At step 802, a memory location in need of repair is determined, the memory location contained in a word and being already located within fuse data. For example, it may be determined that a memory location already contained in a word (e.g., word 306-0, 306-2, . . . 306-N) may be faulty and in need of repair. The detection of the fault may be determined after fuse data has been blown. Thus, the word (e.g., word 306-0, 306-2, . . . 306-N) is located within the blown-fuse data (e.g., fuse 304).

At step 804, a repair-word is determined to be applied to the word stored at the memory location within the fuse data, the repair-word including a first portion indicating a memory subsystem of the memory location in need of repair, a second portion indicating a specific memory within the memory subsystem, and a third portion indicating built-in signature register data (e.g., signature) for the memory location. For example, a repair-word (e.g., repair 104) may be received from a repair controller (e.g., repair controller 102). The repair-word (e.g., repair-word 104) includes a first portion (e.g., SYSTEM_ID 106) that indicates a memory subsystem of the memory location in need of repair. The repair-word (e.g., repair-word 104) includes a second portion (e.g., MEMORY_ID 108) that indicates a specific memory with the memory subsystem indicated by the first portion (e.g., SYSTEM_ID 106). A third portion (e.g., REPAIR_SIG 110) indicates built-in signature register data (e.g., signature) of the word for the specified memory location (e.g., memory location in need of repair).

At step 806, the repair-word (to invalidate or modify) is applied, by a repair controller, to the word stored at the memory location within the fuse data, the applying effective to invalidate the word stored at the memory location within the fuse data. For example, the repair controller (e.g., repair controller 102) applies the repair-word (e.g., repair-word 104) to the word (e.g., word 306-0, 306-2, . . . 306-N) stored at the memory location (e.g., address 308-0, 308-2, . . . 308-N) stored within the fuse data (e.g., fuse 304). The repair-word (e.g., repair word 104) may invalidate the word as discussed herein. For example, the repair-word may modify the first portion (e.g., SYSTEM_ID 106) of the word, the second portion (e.g., MEMORY_ID 108) of the word, or all three portions (e.g., SYSTEM_ID 106, MEMORY_ID 108, REPAIR_SIG 110) of the word to an invalid entry that prevents access to the memory location in need of repair. For example, the bits may be changed to be all 1s for the first portion (e.g., SYSTEM_ID 106) of the word, the second portion (e.g., MEMORY_ID 108) of the word, or all three portions (e.g., SYSTEM_ID 106, MEMORY_ID 108, REPAIR_SIG 110) of the word.

In another application, the repair controller (e.g., repair controller 310) may be configured to modify the third portion (e.g., REPAIR_SIG 110 or signature) of the word based on location-based priority. In other words, the repair controller (e.g., repair controller 310) overwrites a signature portion of a word stored in fuse data (e.g., fuse 304) each time it is received. The repair controller (e.g., repair controller 310) is configured to sequentially read words (e.g., words 306-0, 306-2, . . . 306-N) from a lowest address (e.g., address 308-0) to a highest address (e.g., address 308-N) within the fuse data (e.g., fuse 304).

FIG. 9 is a flowchart that illustrates a method 900 for reprogrammable memory repair, which includes operations 902 through 906 and operational operations 908 through 912.

The method 900 for reprogrammable memory repair may be a continuation of the method 800 for reprogrammable memory repair of FIG. 8.

At step 902, at least a portion of fuse data is downloaded from a fuse to a shadow storage. For example, at least a portion of fuse data (e.g., words 406-0, 406-1, . . . 406-N) is downloaded from a fuse (e.g., fuse 404) to a shadow storage (e.g., shadow storage 410).

At step 904, a memory location in need of repair is determined, the memory location being located within fuse data downloaded to the shadow storage. For example, a repair controller (e.g., repair controller 414) may send a command requesting a specified word (e.g., word 406-0, 406-1, . . . 406-N) be sent to the repair controller (e.g., repair controller 414). The shadow storage (e.g., shadow storage 410) sends the requested word (e.g., word 406-0, 406-1, . . . 406-N) to the repair controller (e.g., repair controller 414).

At step 906, word data within the memory location in need of repair is overwritten with automatic testing equipment. For example, automatic test equipment (ATE 418) that is coupled with the repair controller (e.g., repair controller 414) overwrites the word (e.g., word 406-0, 406-1, . . . 406-N) received from the shadow storage (e.g., shadow storage 410).

At step 908, the word data is optionally invalidated. For example, the automatic test equipment (e.g., ATE 418) invalidates the word (e.g., word 406-0, 406-1, . . . 406-N). The automatic test equipment (e.g., ATE 418) may invalidate the word by modifying one or more portions of the word (e.g., word 406-0, 406-1, . . . 406-N). For example, the automatic test equipment (e.g., ATE 418) may change the bits within one or more portions of the word (e.g., word 406-0, 406-1, . . . 406-N) to become all 1s as discussed herein. In this aspect, reprogrammable memory repair can prevent access to a faulty memory location.

At step 910, the word data is optionally erased. For example, the automatic test equipment (e.g., ATE 418) may erase the word (e.g., word 406-0, 406-1, . . . 406-N). In this aspect, reprogrammable memory repair can prevent access to a faulty memory location.

At step 912, the word data is optionally modified. For example, the automatic test equipment (e.g., ATE 418) modifies the word (e.g., word 406-0, 406-1, . . . 406-N). For example, the automatic test equipment (e.g., ATE 418) can modify the various portions (e.g., SYSTEM_ID 106, MEMORY_ID 108, REPAIR_SIG 110) of the word (e.g., word 406-0, 406-1, . . . 406-N). In this aspect, reprogrammable memory repair can prevent access to a faulty memory location or enable access to a faulty memory location if the location was erroneously identified as being faulty.

For the methods described herein and the associated flowchart(s) and flow diagram(s), the orders in which operations are shown and/or described are not intended to be construed as a limitation. Instead, any number or combination of the described method operations can be combined in any order to implement a given method or an alternative method, including by combining operations from the flowchart or diagram and the earlier-described techniques into one or more methods. Operations may also be omitted from or added to the described methods. Further, described operations can be implemented in fully or partially overlapping manners.

### CONCLUSION

Unless context dictates otherwise, use herein of the word “or” may be considered use of an “inclusive or,” or a term that permits inclusion or application of one or more items that are linked by the word “or” (e.g., a phrase “A or B” may be interpreted as permitting just “A,” as permitting just “B,” or as permitting both “A” and “B”). Also, as used herein, a phrase referring to “at least one of” a list of items refers to any combination of those items, including single members. For instance, “at least one of a, b, or c” can cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c, or any other ordering of a, b, and c). Further, items represented in the accompanying figures and terms discussed herein may be indicative of one or more items or terms, and thus reference may be made interchangeably to single or plural forms of the items and terms in this written description.

Although implementations for reprogrammable memory repair have been described in language specific to certain features and/or methods, the subject of the appended claims is not necessarily limited to the specific features or methods described. Rather, the specific features and methods are disclosed as example implementations for reprogrammable memory repair.

What is claimed is:

1. A method comprising:
determining a memory location in need of repair, the memory location contained in a word and being already located within fuse data;
determining a repair-word to be applied to the word stored at the memory location within the fuse data, the repair-word including a first portion indicating a memory subsystem of the memory location in need of repair, a second portion indicating a specific memory within the memory subsystem of the memory location, and a third portion indicating built-in signature register data for the memory location; and
applying the repair-word, by a repair controller, to the word stored at the memory location within the fuse data, the applying effective to invalidate the word stored at the memory location within the fuse data by modifying the first portion, the second portion, or the first, second, and third portions of the repair-word.

2. The method of claim 1, further comprising writing the word to a built-in signature register.

3. The method of claim 2, wherein the first portion of the repair-word is used to invalidate the word.

4. The method of claim 2, wherein the second portion of the repair-word is used to invalidate the word.

5. The method of claim 2, wherein the first portion of the repair-word, the second portion of the repair-word, and the third portion of the repair-word are used to invalidate the word.

6. The method of claim 2, wherein applying the repair-word, by the repair controller, further comprises replacing a portion of the word with a repair-word having a higher location-based priority than the word.

7. The method of claim 6, wherein the first portion of the repair-word is identical to a first portion of the word, the second portion of the repair-word is identical to a second portion of the word, and the third portion of the repair-word is used to replace the portion of the word.

8. A method comprising:
downloading, from a fuse, at least a portion of fuse data to a shadow storage;
determining a memory location in need of repair, the memory location identified within fuse data downloaded to the shadow storage; and
overwriting, with automatic test equipment, word data within the memory location in need of repair.

9. The method of claim 8, wherein overwriting the word data comprises invalidating the word data.

10. The method of claim 8, wherein overwriting the word data comprises erasing the word data.

11. The method of claim 8, wherein overwriting the word data comprises modifying the word data.

12. A system comprising:
a fuse having a plurality of memory locations, each memory location of the plurality of memory locations containing a word;
a fuse controller coupled with the fuse, the fuse controller configured to access the plurality of memory locations; and
a repair controller coupled with the fuse controller, the repair controller configured to individually repair the word of a selected location of the plurality of memory locations.

13. The system of claim 12, wherein the repair controller is configured to generate a repair-word to individually repair the word of the selected location.

14. The system of claim 13, wherein the repair-word includes a first portion indicating a memory subsystem of the selected location, a second portion indicating a specific memory within the memory subsystem of the selected location, and a third portion indicating built-in signature register data for the selected location.

15. The system of claim 14, further comprising:
a logic portion configured to decode the first portion of the repair-word to determine a specified memory subsystem; and
a decoder configured to decode the specific memory within the specified memory subsystem of the selected location and the built-in signature register data for the selected location.

16. The system of claim 15, wherein the selected location is repaired by invalidating the word of the selected location.

17. The system of claim 15, wherein the word of the selected location is invalidated by modifying the first portion of the word, the second portion of the word, or the first, second, and third portions of the word.

18. The system of claim 13, wherein the repair controller is configured to repair the word of the selected location based on location priority replacing the word when a word, with a higher address, for the selected location is received.

19. The system of claim 13 wherein the word of the selected location includes a first portion indicating a memory subsystem, a second portion indicating a specific memory within the memory subsystem, and a third portion indicating built-in signature register data and further comprising:
a shadow storage coupled with the fuse and the repair controller; and
an automatic test equipment coupled with the shadow storage, the automatic test equipment configured to overwrite the third portion of the word of the selected location.

20. The system of claim 19, wherein the automatic test equipment overwrites the third portion of the word of the selected location by:
invalidating the third portion of the word;
erasing the third portion of the word; or
modifying the third portion of the word.
